(19) United States
(12) Patent Application Publication
(10) Pub. No.: US 2026/0068616 A1
(43) Pub. Date: Mar. 5, 2026

(54) PACKAGE STRUCTURE AND METHOD OF MANUFACTURING THE SAME

(71) Applicant: Taiwan Semiconductor Manufacturing Company, Ltd., Hsinchu (TW)

(72) Inventors: Ching-Wen Chen, Kaohsiung City (TW); Wei-Chung Chang, Taipei City (TW); Zi-Jheng Liu, Taoyuan City (TW); Chih-Huang Li, Taichung (TW); Tzung-Hui Lee, New Taipei City (TW); Hung-Jui Kuo, Hsinchu City (TW)

(73) Assignee: Taiwan Semiconductor Manufacturing Company, Ltd., Hsinchu (TW)

(21) Appl. No.: 18/826,079

(22) Filed: Sep. 5, 2024

(51) Int. Cl. H01L 21/768; H01L 21/311; H01L 21/48; H01L 23/00; H01L 23/29; H01L 23/498; H01L 25/18

(52) U.S. Cl. CPC H01L 21/76871

(57) ABSTRACT

A method of manufacturing the package structure includes providing a carrier on which first dies and second dies are respectively bonded to form stacks and an encapsulant laterally encapsulating the stacks, forming a dielectric layer over the stacks, forming openings in the dielectric layer to expose a portion of the second dies, forming trenches in the gaps through the encapsulant to expose the carrier, forming a cover layer on sidewalls of the trenches and sidewalls of the openings, and conformally forming a seed layer on the trenches, the openings, the carrier, the cover layer, the encapsulant, and the dielectric layer, forming a mask layer to cover a portion of the seed layer and expose the seed layer in the openings, and performing a plating process to form a conductive portion in the openings using the seed layer.

### BACKGROUND

Integrated circuits are having increasingly more functions. In order to integrate more functions together, a plurality of device dies are manufactured, and are packaged together in a packaging process. The plurality of device dies are electrically interconnected in order to work together. Signals are transferred between the device dies and packages to implement the intercommunication.

With the increasingly demanding requirement of high-performance applications, optical signals are increasingly used for signal communications due to their high speed and low latency.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top view of a package structure in accordance with some embodiments of the present disclosure.

FIG. 2A through 2M illustrate cross-sectional views of a process for the formation of a package structure in accordance with some embodiments of the present disclosure.

FIG. 3A illustrates an enlarged view of a first portion of the package structure of FIG. 2H.

FIG. 3B illustrates an enlarged view of a second portion of the package structure of FIG. 2H.

FIG. 4A through 4D illustrate cross-sectional views of a process for the formation of a package structure in accordance with some embodiments of the present disclosure.

FIG. 5A through 5E illustrate cross-sectional views of a process for the formation of a package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “on,” “over,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package structure including a plurality of photonic integrated circuit (PIC) die and a plurality of electronic integrated circuit (EIC) is formed. The processes for forming the package structure are provided. In accordance with some embodiments of the present disclosure, the PIC dies and the EIC dies are bonded to each other and surrounded by trench. The trench will be placed a fiber array unit (FAU) to input signal, and thus the dimension (such as width/depth) of the trench would be desired to large enough to install the FAU. However, the large trench has rough surfaces resulting in discontinuous seed and worse plating uniformity. Accordingly, a cover layer is formed on sidewalls of the trench before the formation of seed to control side wall roughness for continues seed deposition and uniform plating performance. Continues seed and good uniform plating performance would be accomplished according to the disclosure. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

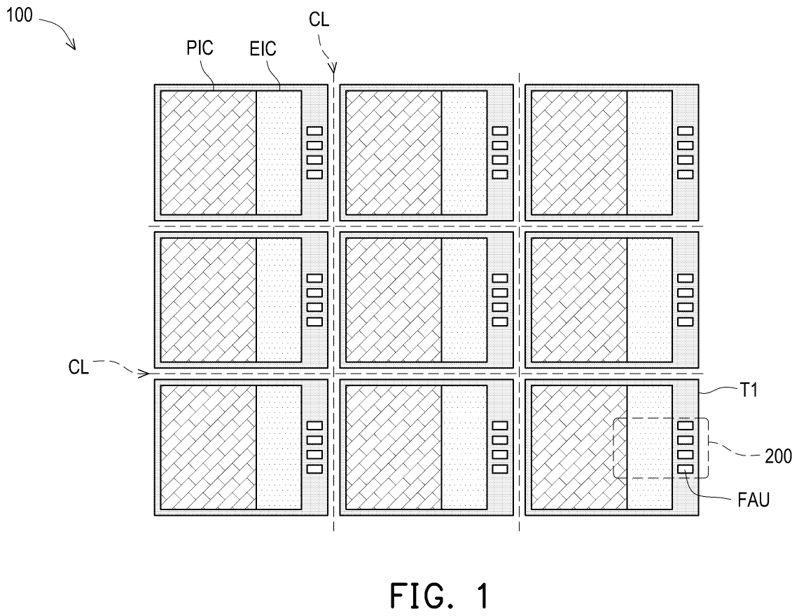

FIG. 1 illustrates a top view of a package structure in accordance with some embodiments of the present disclosure.

Referring to FIG. 1, the package structure 100 includes a plurality of first dies (e.g. electronic integrated circuit dies marked as EIC) and a plurality of second dies (e.g. photonic integrated circuit dies marked as PIC). In some embodiments, the first die may be other than an electronic integrated circuit die, and the second die may be other than a photonic integrated circuit die. In some embodiments, the first dies and the second dies have different functions and bonded to each other. The second dies are over the first dies in FIG. 1; however, it is not limited thereto. In some alternative embodiments, the first dies are over the second dies. One of the first dies EIC and one of corresponding second dies PIC bonded thereto constitute a package component, and the package components are surrounded by trenches T1 and defined by the cut lines CL. In other words, the trenches T1 are formed in gaps among the package components. In some embodiments, transmitting elements such as fiber array unit FAU are disposed in the trenches T1 of the package structure 100. Accordingly, in each of the trenches T1, at least one portion with the transmitting elements FAU has larger dimension than other portions without the transmitting elements FAU. Since large trench may have rough surfaces (or side walls) due to uncontrolled etching process, the present disclosure provides methods to reduce roughness of trench sidewalls and even to fill recess at the trench sidewalls.

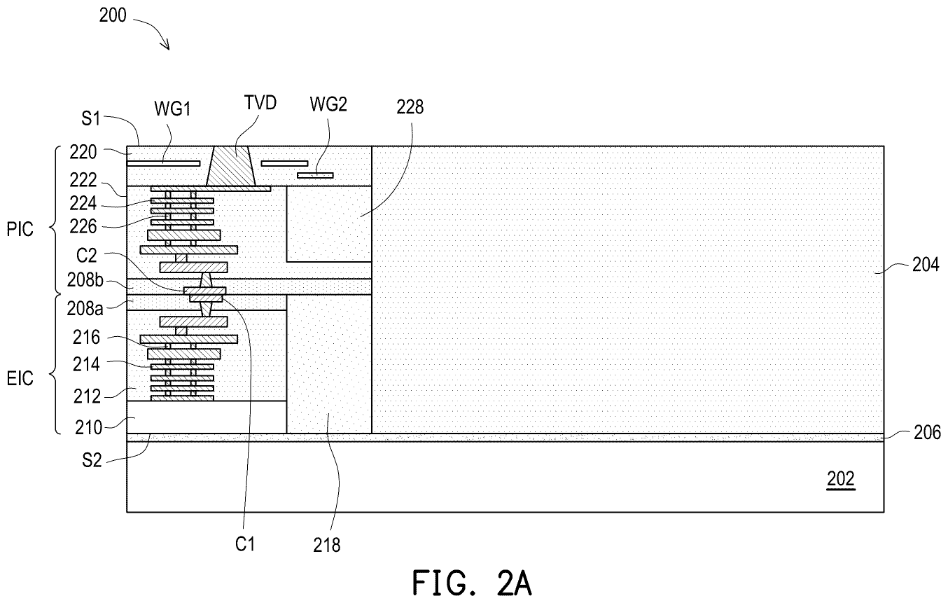

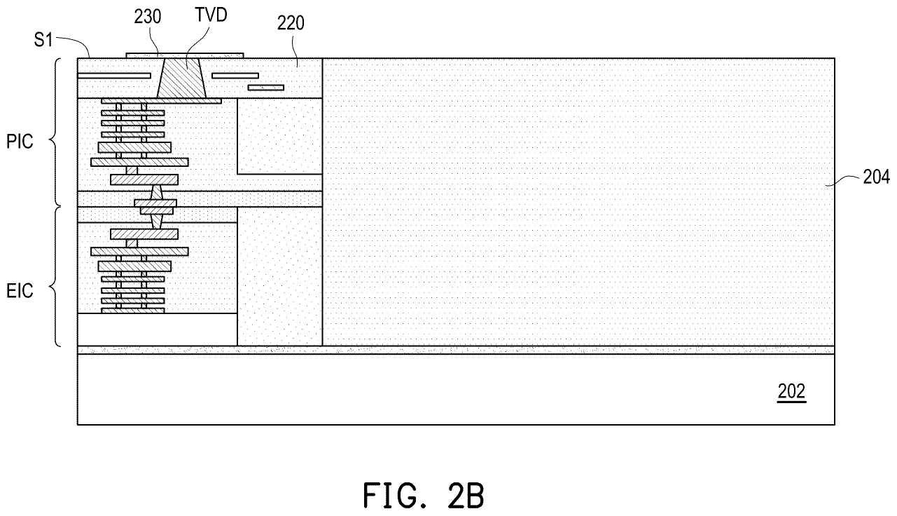

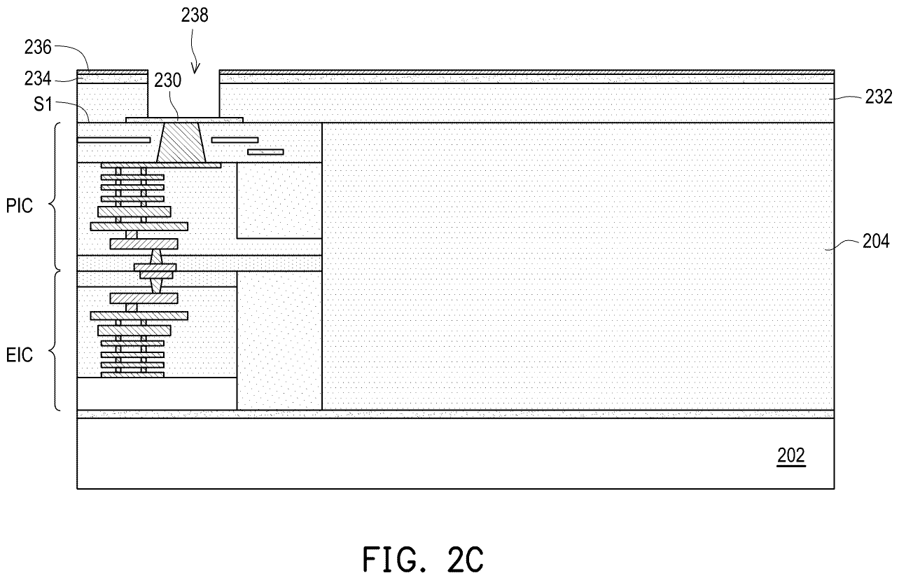

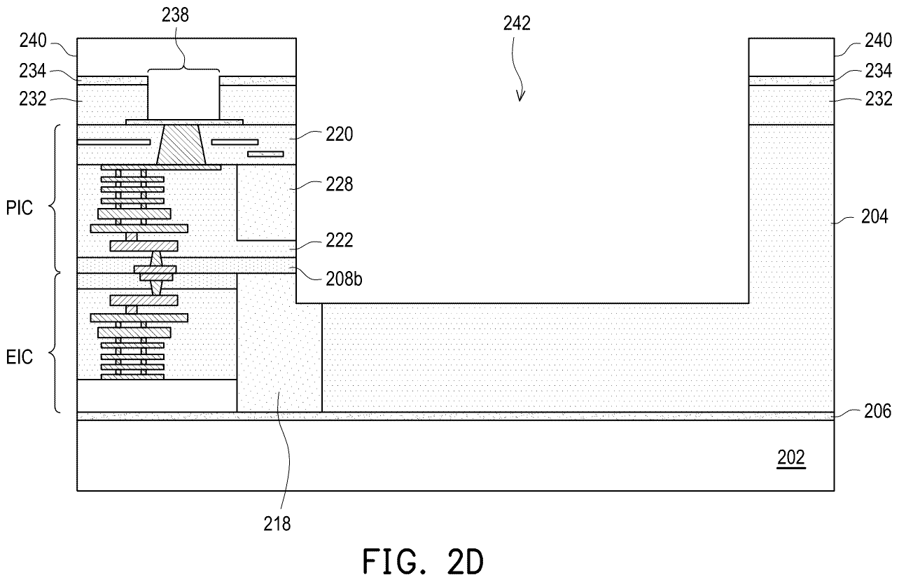

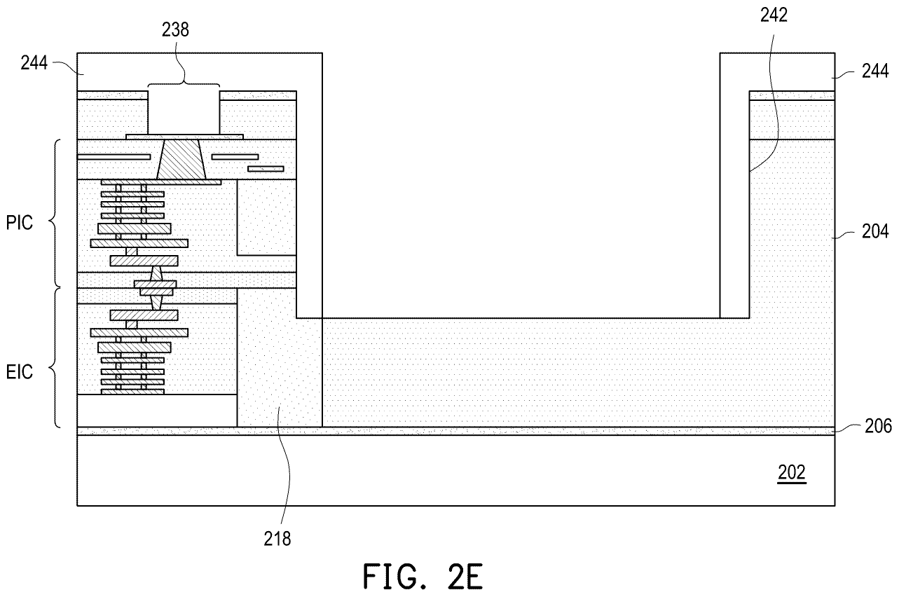

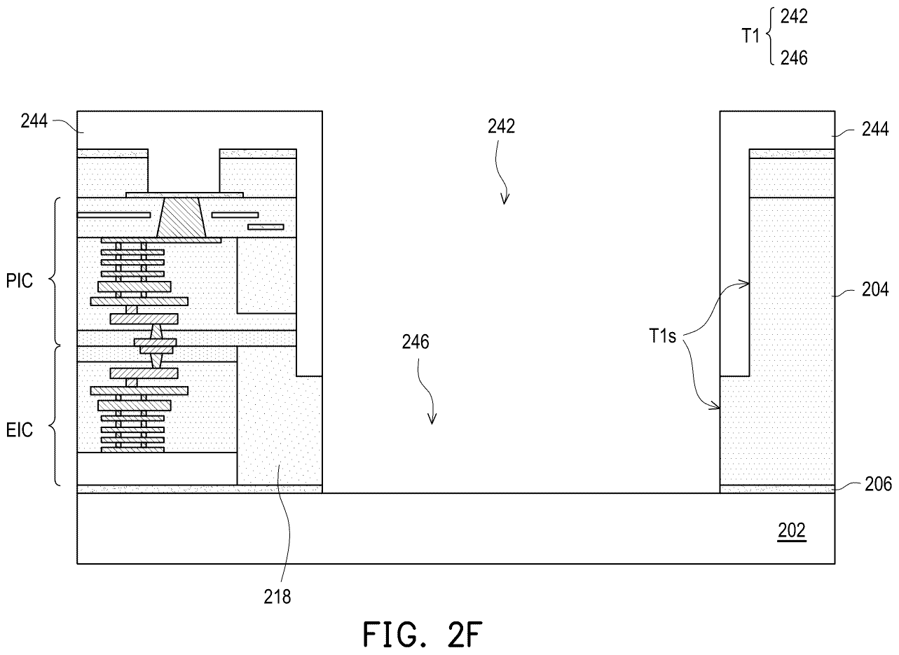

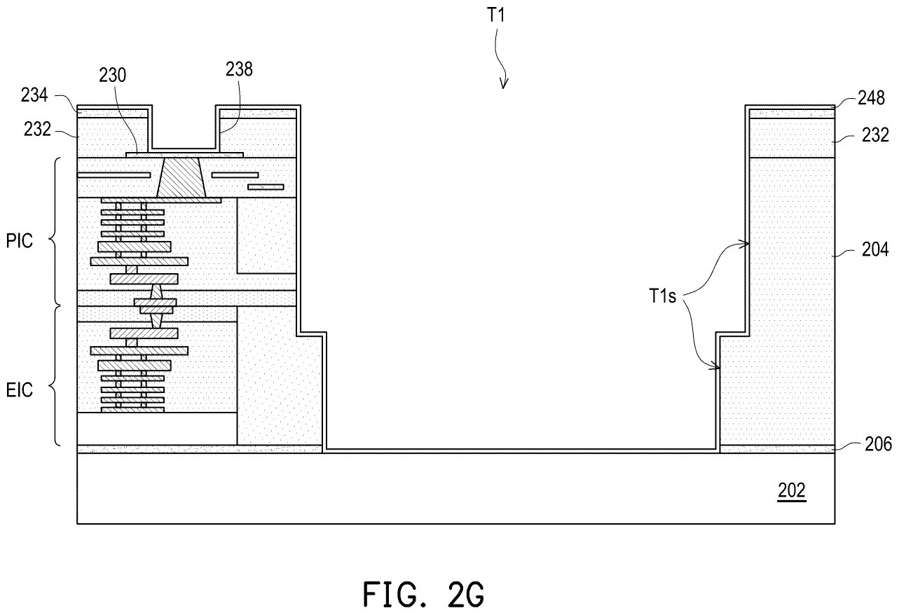

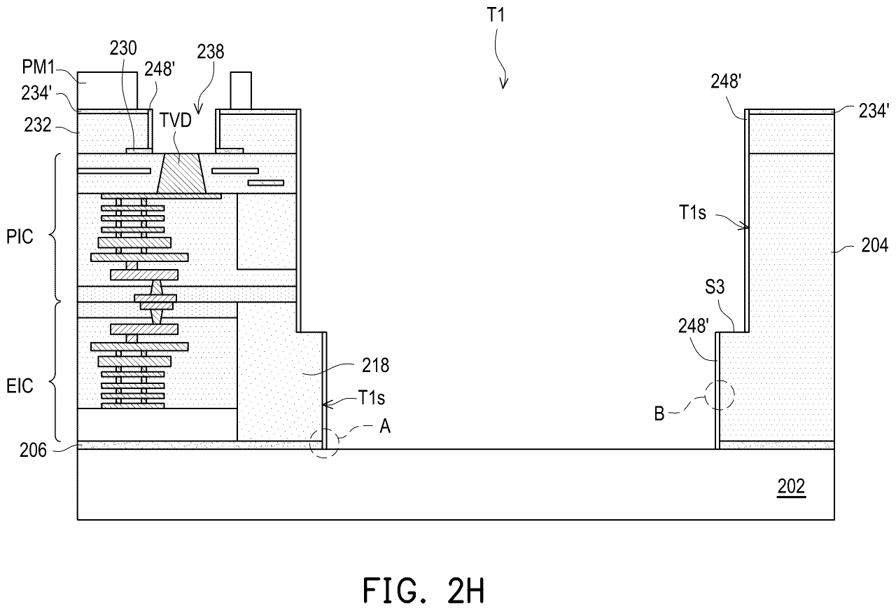

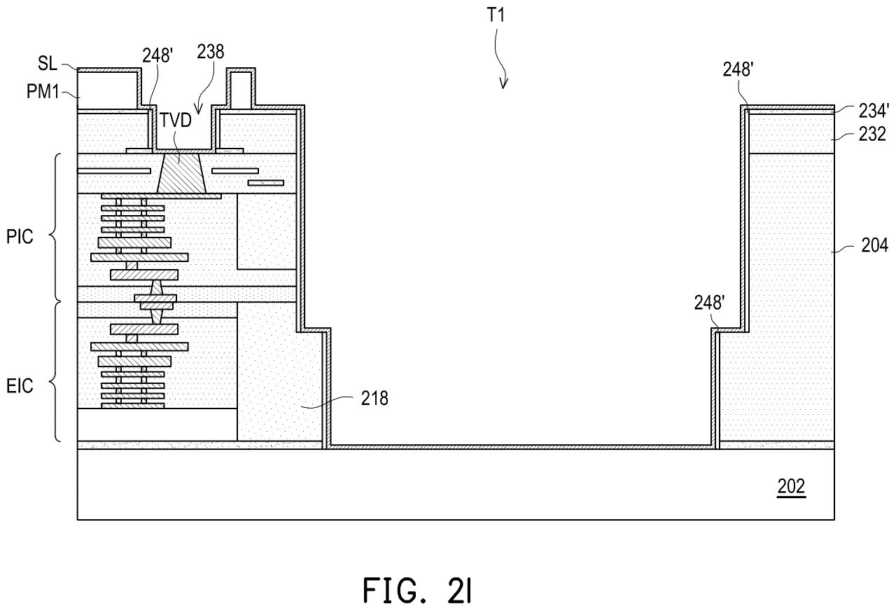

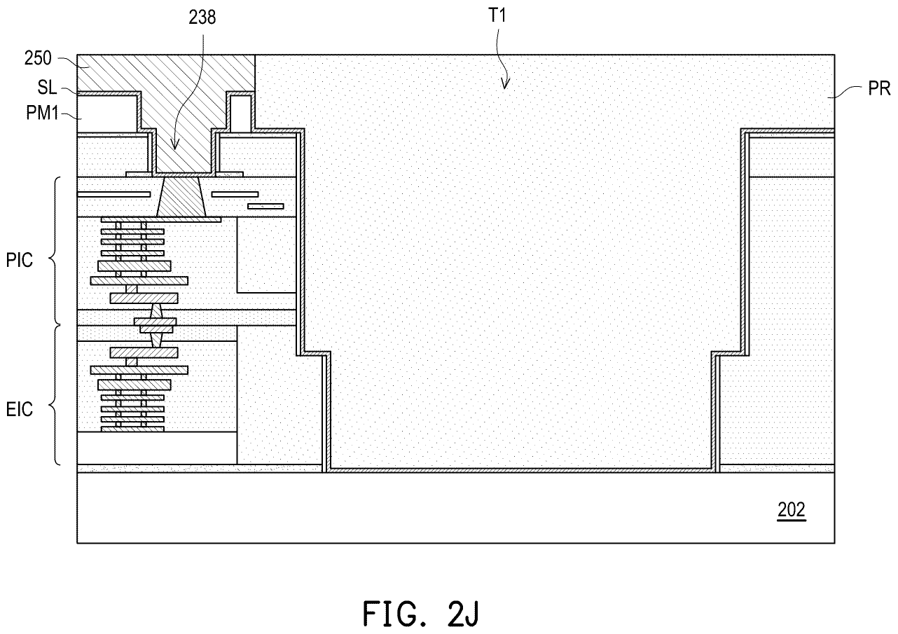

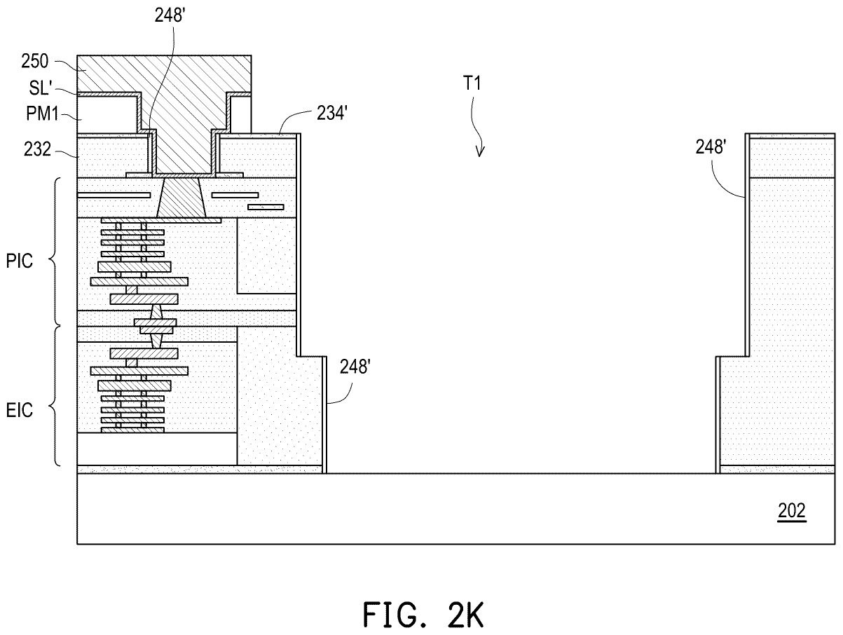

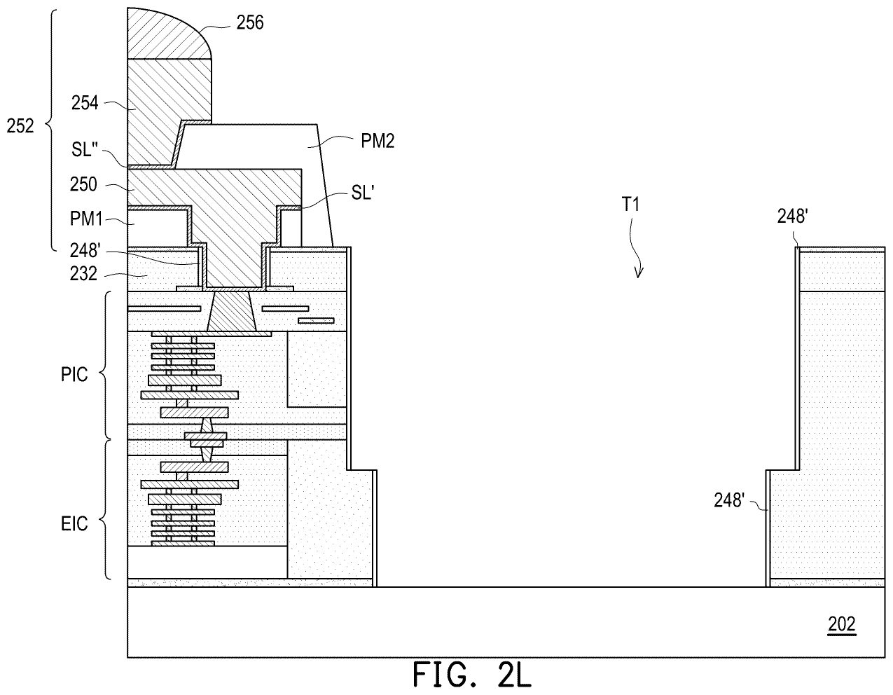

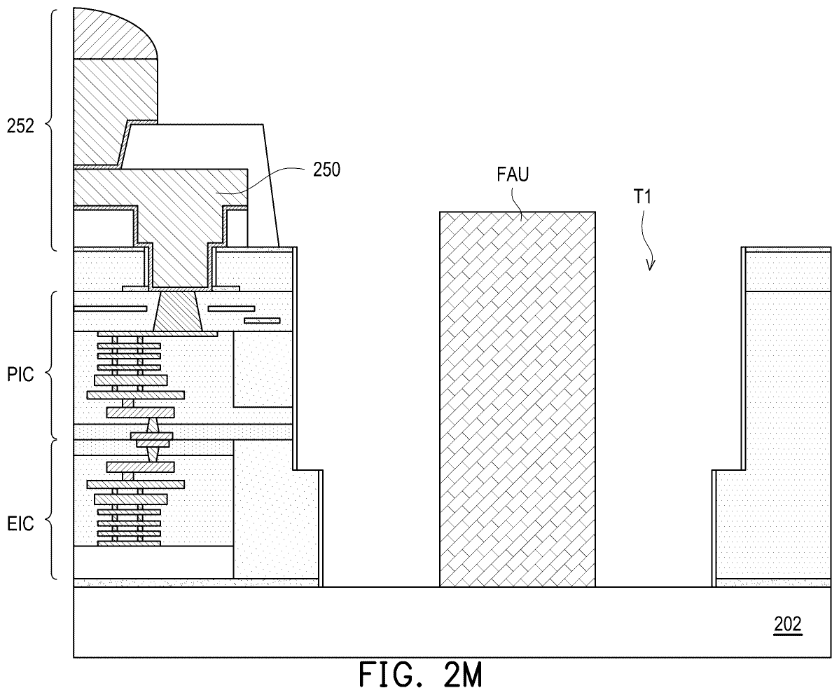

FIG. 2A through 2M illustrate cross-sectional views of a process for the formation of a package structure in accordance with some embodiments of the present disclosure. For the purpose of simplicity and clarity, known or unnecessary components are omitted from those figures.

Referring to FIG. 2A, the package structure 200 is a cross-sectional structure of a partial of the package structure 100 along a line from left to right in FIG. 1. The first dies EIC and the second dies PIC are formed respectively. The first die EIC may include a substrate 210, a dielectric layer 212 over the substrate 210, an interconnection structure including conductive patterns 214 and conductive vias 216 formed in the dielectric layer 212, and a dielectric layer 208a with a bonding pad/vias C1 over the dielectric layer 212. The conductive patterns 214 are electrically connected to each other through the conductive vias 216. In some embodiments, the interconnection structure are connected to a device (not shown) in the substrate 210. The conductive patterns 214 are electrically connected to each other through the conductive vias 216. In some embodiments, the interconnection structure are connected to a device (not shown) in the substrate 210. In some embodiments, a gap-fill material 218 is formed to gap fill the space surrounding the substrate 210, the dielectric layer 212, and the interconnection structure.

The second die PIC may include a dielectric layer 220, a first waveguide WG1 and a second waveguide WG2 formed in the dielectric layer 220, a through dielectric vias TVD formed in and through the dielectric layer 220, a dielectric layer 222 below the dielectric layer 220, an interconnection structure including conductive patterns 224 and conductive vias 226 formed in the dielectric layer 222, and a dielectric layer 208b with a bonding pad/vias C2 below the dielectric layer 222. The through dielectric vias TVD is electrically connected to the topmost conductive pattern 224 of the interconnection structure. In some embodiments, the through dielectric vias TVD may include copper, aluminum, tungsten, alloys thereof, and/or any other suitable materials. The conductive patterns 224 are electrically connected to each other through the conductive vias 226. In some embodiments, the interconnection structure are connected to an optical device (not shown) in the dielectric layer 220. In some embodiments, an oxide material 228 is formed between the dielectric layer 220 and the dielectric layer 222.

In some embodiments, the second die PIC is a photonic integrated circuit die. The photonic integrated circuit die can transmit, receive, convert, modulate, demodulate, or otherwise process optical signals. For example, the photonic integrated circuit die can convert electrical signals from a processor die (e.g. the first die EIC) to optical signals, and convert optical signals to electrical signals. The photonic integrated circuit die can communicate such optical signals through the optical pathway with one or more other photonic integrated circuit dies. The photonic integrated circuit die can receive the optical signals from optical fiber, and transmit and/or receive the optical signals via one or more waveguides of the optical pathway (e.g. the first waveguide WG1 and the second waveguide WG2). Accordingly, the photonic integrated circuit die is responsible for the input/output (I/O) of optical signals to/from the optical pathway.

In some embodiments, a top surface of the bonding pad/vias C1 and a top surface of the dielectric layer 208a may be substantially located at the same level height, and a bottom surface of the bonding pad/vias C2 and a bottom surface of the dielectric layer 208b may be substantially located at the same level height. In some embodiments, the first die EIC may be bonded to the second die PIC through a hybrid bonding process. It should be understood that the plurality of first dies EIC can be bonded to the plurality of second dies PIC as shown FIG. 1.

In some embodiments, a material of the dielectric layer 208a, the dielectric layer 208b, the dielectric layer 212, the dielectric layer 220, and the dielectric layer 222 includes polyimide, epoxy resin, acrylic resin, phenol resin, benzocyclobutene (BCB), polybenzooxazole (PBO), or any other suitable polymer-based dielectric material. Alternatively, the dielectric layer 208a, the dielectric layer 208b, the dielectric layer 212, the dielectric layer 220, and the dielectric layer 222 may be formed of oxides or nitrides, such as silicon oxide, silicon nitride, or the like. The dielectric layer 208a, the dielectric layer 208b, the dielectric layer 212, the dielectric layer 220, and the dielectric layer 222, for example, may be formed by suitable fabrication techniques such as spin-on coating, chemical vapor deposition (CVD), plasma-enhanced chemical vapor deposition (PECVD), or the like. In some embodiments, the bonding pad/vias C1 and the bonding pad/vias C2 may be made of aluminum, titanium, copper, nickel, tungsten, or alloys thereof. In some embodiments, a material of the conductive patterns 214, the conductive vias 216, the conductive patterns 224, and the conductive vias 226 includes aluminum, titanium, copper, nickel, tungsten, or alloys thereof. The conductive patterns 214, the conductive vias 216, the conductive patterns 224, and the conductive vias 226 may be formed by, for example, electroplating, deposition, and/or photolithography and etching. In some embodiments, the conductive patterns 214 and the underlying conductive vias 216 may be formed simultaneously, and/or the conductive patterns 224 and the underlying conductive vias 226 may be formed simultaneously. It should be noted that the number of the dielectric layer 212, the number of the dielectric layer 220, the number of the dielectric layer 222, the number of the conductive patterns 214, the number of the conductive vias 216, the number of the conductive patterns 224, and the number of the conductive vias 226 illustrated in FIG. 2A are merely for illustrative purposes, and the disclosure is not limited thereto. In some alternative embodiments, fewer or more layers of the conductive patterns 214/224 or the conductive vias 216/226 may be formed depending on the circuit design. In some alternative embodiments, the gap-fill material 218 and the oxide material 228 includes oxides, such as silicon oxide or the like.

As illustrated in FIG. 2A, an encapsulant 204 laterally encapsulates the stack including the first die EIC and the second die PIC. A top surface of the encapsulant 204 may be coplanar with a top surface of the dielectric layer 220 to form a first surface S1. The stack and the encapsulant 204 are bonded to a carrier 202 with a bonding layer 206. The carrier 202 may be a carrier wafer. The carrier wafer is used as a platform or a support for a packaging process described below. In some embodiments, the carrier wafer comprises a semiconductor material (such as silicon, or the like), a dielectric material (such as glass, a ceramic material, quartz, or the like), a combination thereof, or the like. In some embodiments, the stack and the encapsulant 204 may be bonded through wafer to wafer (W2W) bonding or the like. For example, W2W bonding may employ a fusion bonding technique to bond carrier 202 using the bonding layer 206 comprising an oxide. The fusion bonding process may include forming the bonding layer 206 over the carrier 202, activating an exposed surface of the bonding layers 206 (e.g., in a plasma process), and cleaning bonding layers 206 after activation. The fusion bonding process may further include contacting the activated surfaces of the bonding layers 206 to a second surface S2 including a bottom surface of the substrate 210, a bottom surface of the gap-fill material 218 and a bottom surface of the encapsulant 204, followed by performing a thermal annealing process.

Referring to FIG. 2B, a buffer layer 230 may be formed on the surface S1 to cover and protect the through dielectric vias TVD. In some embodiments, the buffer layer 230 may be a dielectric material layer. In some embodiments, the method of forming the buffer layer 230 includes depositing a whole buffer layer by suitable fabrication techniques such as CVD, PECVD, or the like, and then patterning the whole buffer layer to form the buffer layer 230 covering the through dielectric vias TVD.

Referring to FIG. 2C, a dielectric layer 232 is formed over the surface S1 to cover the encapsulant 204, the second die PIC, and the buffer layer 230. In some embodiments, a first mask layer 234 and a second mask layer 236 are formed on the dielectric layer 232 orderly. The first mask layer 234 and the second mask layer 236 are different materials with etching selectivity. In some embodiments, the first mask layer 234 may be thicker than the buffer layer 230. The second mask layer 236 is patterned to expose a portion of the first mask layer 234, and then the first mask layer 234 is etched to expose a portion of the dielectric layer 232 by using the second mask layer 236 as an etching mask. The exposed dielectric layer 232 is etched to expose a portion of the buffer layer 230 by using the first mask layer 234 as an etching mask. Accordingly, an opening 238 is formed in the dielectric layer 232. In some embodiments, the cross-section shape of the opening 238 is square, rectangle, trapezoid, inverted trapezoid, or the like. Although only one opening 238 is shown in FIG. 2C, it should be noted that the number of the opening 238 are merely for illustrative purposes, and the disclosure is not limited thereto. In some embodiments, a plurality of openings 238 may be formed depending on the circuit design.

Referring to FIG. 2D, a first mask pattern 240 is formed over the carrier 202 after removing the second mask layer 236 in FIG. 2C. In some embodiments, the first mask pattern 240 is a photoresist pattern, and a coating process as well as a lithography process may be used for forming the first mask pattern 240. The first mask pattern 240 covers most of the first die EIC and the second die PIC and exposes a portion of the first mask layer 234 corresponding to a location where a trench will be formed. By using the first mask pattern 240 as an etching mask, a first patterning process is performed to etch the first mask layer 234, the dielectric layer 232, and an upper portion of the encapsulant 204 for forming an upper recess 242. In some embodiments, the first patterning process may includes a dry etch (e.g., reactive ion etching), a wet etch, and/or a combination thereof. In some embodiments, portions of the dielectric layer 220, the oxide material 228, the dielectric layer 222, the dielectric layer 208b, and the gap-fill material 218 may be etched during the first patterning process.

Referring to FIG. 2E, after removing the first mask pattern 240 in FIG. 2D, a second mask pattern 244 is formed over the carrier 202. In some embodiments, the remained first mask pattern 240 may be completely removed by a stripping process or an ashing process. In some embodiments, the second mask pattern 244 is a photoresist pattern, and a coating process as well as a lithography process may be used for forming the second mask pattern 244. The second mask pattern 244 covers the first die EIC, the second die PIC, and a portion of the upper recess 242 and exposes a portion of the encapsulant 204.

Referring to FIG. 2F, by using the second mask pattern 244 as an etching mask, a second patterning process is performed to etch a lower portion of the encapsulant 204 under the upper recess 242 and the bonding layer 206 to form a lower recess 246. In some embodiments, the second patterning process may includes a dry etch (e.g., reactive ion etching), a wet etch, and/or a combination thereof. The lower recess 246 and the upper recess 242 compose a trench T1, and in the cross-sectional view, the sidewalls T1s of the trench T1 have a stepped profile. Accordingly, the trench T1 is a groove that is wide at the top and narrow at the bottom. In the top view of FIG. 1, the trench T1 may be rectangular and have different sizes (e.g. widths) at different sides.

Referring to FIG. 2G, after removing the second mask pattern 244 in FIG. 2F, a cover layer 248 is conformally deposited over the carrier 202 using suitable fabrication techniques such as CVD, a subatmospheric CVD (SACVD), a flowable CVD, ALD, or the like. In some embodiments, the remained second mask pattern 244 may be completely removed by a stripping process or an ashing process. In some embodiments, the cover layer 248 may be a silicon nitride layer, an oxide layer, or a combination thereof. In some embodiments, the oxide layer may include an oxide such as silicon oxide, silicon oxynitride, silicon oxycarbide, SiOCN, etc. In some embodiments, the cover layer 248 is disposed on the carrier 202 exposed by the trench T1, the sidewalls T1s, the first mask layer 234, sidewalls of the opening 238 and the buffer layer 230 exposed by the opening 238. In some embodiments, the cover layer 248 may be thinner than the buffer layer 230. In some embodiments, a total thickness of the cover layer 248 and the buffer layer 230 is equal to or less than a thickness of the first mask layer 234.

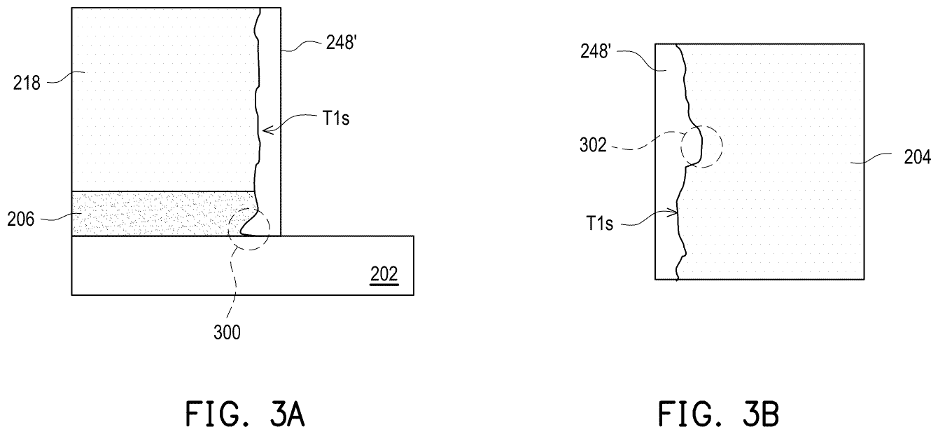

Referring to FIG. 2H, the cover layer 248 is etched back to expose the buffer layer 230 in the opening 238 and to keep the cover layer 248′ on the sidewalls T1s of the trench T1. In some embodiments, the surfaces S3 parallel to the surface of the carrier 202 in the trench T1 are also exposed after etching back. Since the trench T1 has large dimension, the sidewalls T1s have rough surfaces as shown in FIG. 3A or undesired recess at bottom corner of the trench T1 as shown in FIG. 3B.

FIG. 3A illustrates an enlarged view of a first portion A of the package structure of FIG. 2H. FIG. 3B illustrates an enlarged view of a second portion B of the package structure of FIG. 2H. In FIG. 3A, there is an undesired recess 300 at bottom corner, and the cover layer 248′ on the sidewalls T1s can fill the undesired recess 300. In FIG. 3B, there is a part 302 with large roughness at the sidewalls T1s, and the cover layer 248′ may also fill the part 302.

Referring to FIG. 2H again, the buffer layer 230 exposed by the opening 238 is removed for subsequent electrical connections, and meanwhile, a top portion of the first mask layer 234 may also be removed if a material of the buffer layer 230 is the same as the first mask layer 234. Accordingly, the remaining first mask layer 234′ is thinner than the first mask layer 234 of FIG. 2G. A patterned polymer layer PM1 is formed on the first mask layer 234′. In some embodiments, the polymer layer PM1 includes a photo-sensitive material such as polybenzoxazole (PBO), polyimide (PI), benzocyclobutene (BCB), a combination thereof or the like.

Referring to FIG. 2I, a seed layer SL is conformally formed on the trenches T1 and the openings 238 to cover the carrier 202, the cover layer 248′, the encapsulant 204, the patterned polymer layer PM1, and the dielectric layer 232. In the presence of the cover layer 248′, the seed layer SL can continuously deposit on the whole surfaces of the trench T1. In other words, side wall roughness can be improved by the cover layer 248′. In some embodiments, the seed layer SL is a metal layer, which may be a single layer or a composite layer including a plurality of sub-layers formed of different materials, and is formed by a PVD process, such as sputtering. For example, the seed layer SL is a titanium/copper (Ti/Cu) composited layer.

Referring to FIG. 2J, a mask layer (e.g. photoresist layer marked as PR) is formed to cover a portion of the seed layer SL and expose a portion of the seed layer SL over the opening 238 and the patterned polymer layer PM1. A plating process is performed to form a conductive portion 250 using the seed layer SL. The conductive portion 250 includes a via structure filled in the opening 238 and a wiring layer on the patterned polymer layer PM1 as a part of a redistribution structure. In some embodiments, the plating process may be electroplating or electroless plating, or the like. In some embodiments, a material of the conductive portion 250 is copper, nickel, titanium, a combination thereof or the like. Although only one conductive portion 250 is shown in FIG. 2J, it should be noted that the number of the conductive portion 250 is basically more than one depending on the circuit design. Since the seed layer SL is a continues film, the conductive portions 250 located at different positions can be formed uniformly. For example, a height of the conductive portion 250 near the trench T1 would be close to that of the conductive portion (not shown) far away the trench T1. If the cover layer 248′ in FIG. 2I is absent, the seed layer SL may discontinue in the trench T1, causing the plating current to crowd at (die) edge, resulting in worse plating uniformity.

Referring to FIG. 2K, after removing the mask layer PR in FIG. 2J, a portion of the seed layer SL exposed by the conductive portion 250 is removed, and the remaining seed layer SL′ is located below the conductive portion 250. In some embodiments, the mask layer PR may be completely removed by a stripping process or an ashing process.

To prove the improvement the plating uniformity of the conductive portions 250, series of experiments are conducted. Certainly, the following experimental data and conditions are provided for the purpose of illustration only, and the disclosure is not limited thereto, but rather encompasses all variations, which are relevant as a result of the teachings provided herein. First, the processes of all samples were the same, but the differences are the comparative sample without trench and cover layer, and each of experimental samples has a silicon nitride cover layer with a thickness of 700 Å and a large trench with a depth of 23 μm and a width of 45 μm. Next, the estimation method includes measuring the height (thickness) of the plated conductive portions over the whole die, and then the plating uniformity can be calculated according to the thickness differences. In the results of the experiments, the plating uniformity of the comparative sample was 5.6%, the plating uniformity of one of the experimental samples was 1.8%, and the plating uniformity of another of the experimental samples was 1.3%. It is found that the plating uniformity was improved in the presence of the cover layer even the whole dies surrounded by a large trench.

Referring to FIG. 2L, in order to form a redistribution structure 252, another patterned polymer layer PM2, another conductive portion 254, and a connector 256 are formed on the conductive portion 250 and the dielectric layer 232. The patterned polymer layer PM2 is formed over the conductive portion 250 and the dielectric layer 232. The process for forming the conductive portion 254 is similar to that for forming the preparation conductive portion 250; for instance, another seed layer SL″ is formed, a mask layer (not shown) is formed to cover a portion of the seed layer SL″, and a plating process is performed to form the conductive portion 254 using the seed layer SL″. The connector 256 is formed over and electrically connected to the conductive portion 254. In some embodiments, the polymer layer PM2 includes a photo-sensitive material such as PBO, PI, BCB, a combination thereof or the like. In some alternative embodiments, the material of the polymer layers PM1 and PM2 may be the same as or different from the material of the encapsulant 204.

In some embodiments, the connector 256 is referred to as conductive terminal. In some embodiments, the connector 256 may be ball grid array (BGA) connector, solder ball, controlled collapse chip connection (C4) bump, or a combination thereof. In some embodiments, the material of the connector 256 includes copper, aluminum, lead-free alloys (e.g., gold, tin, silver, aluminum, or copper alloys) or lead alloys (e.g., lead-tin alloys). The connector 256 may be formed by a suitable process such as evaporation, plating, ball dropping, screen printing and reflow process, a ball mounting process or a C4 process.

Referring to FIG. 2M, a fiber array unit FAU is formed in the trench T1 over the carrier 202 to input signal. FIG. 2M illustrates a box to represent the fiber array unit FAU, but it should be noted that actual fiber array unit may have various components and shapes, and a known actual fiber array unit may be used in the disclosure.

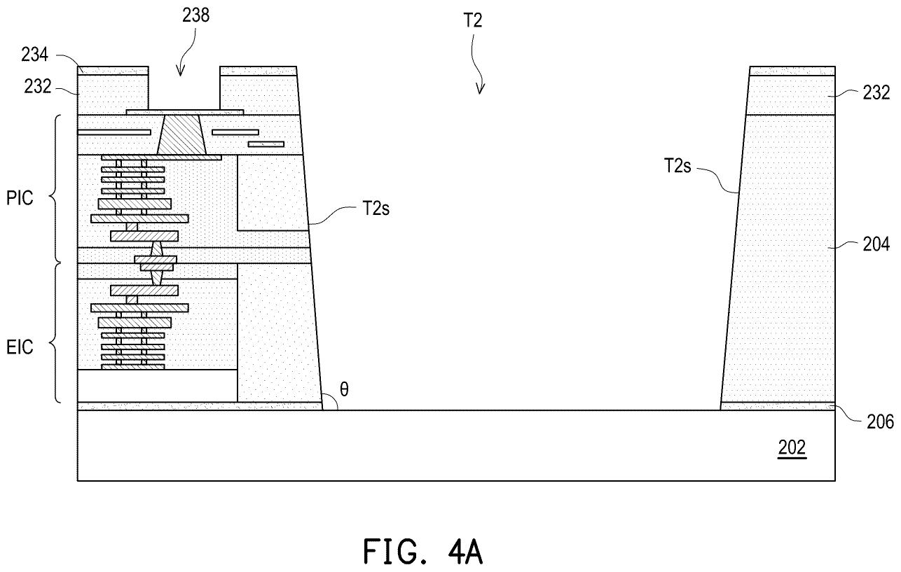

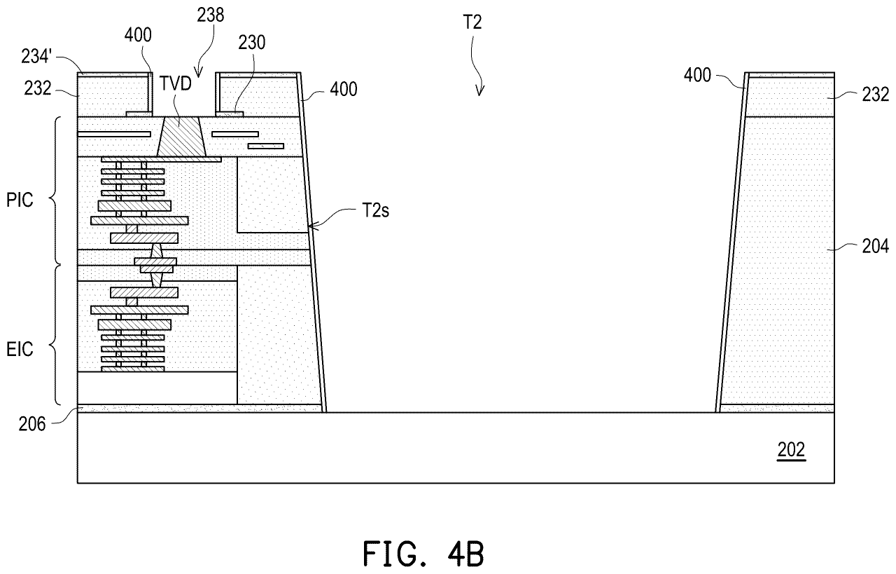

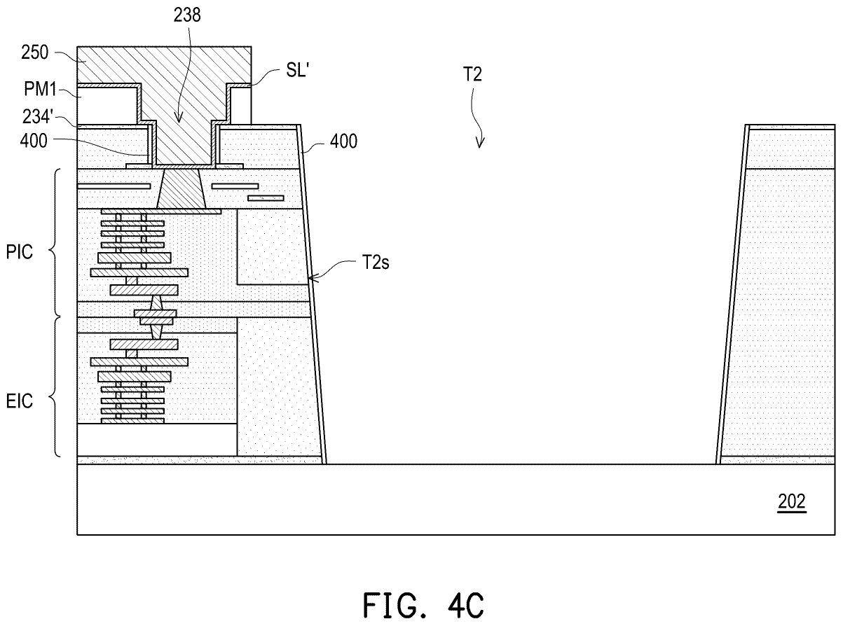

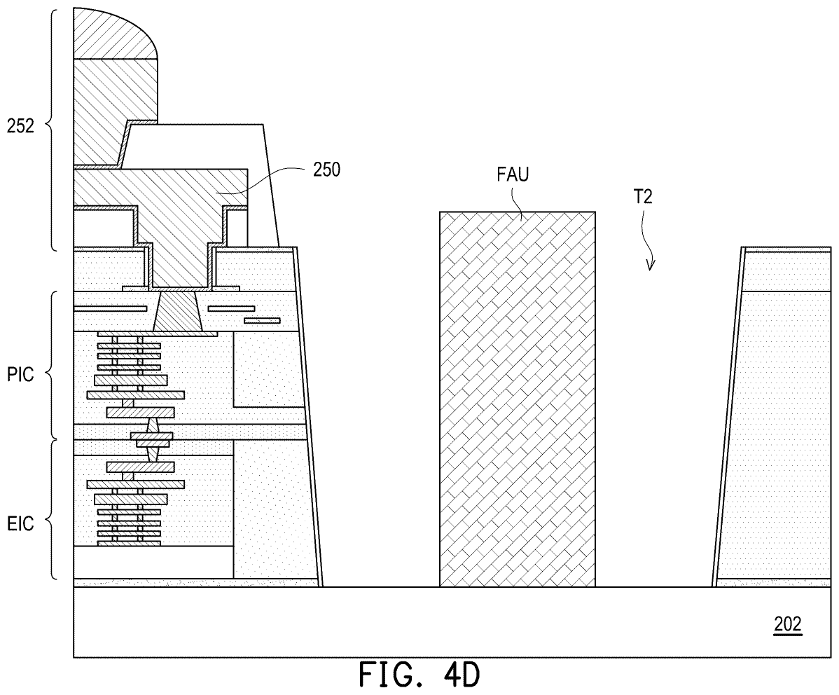

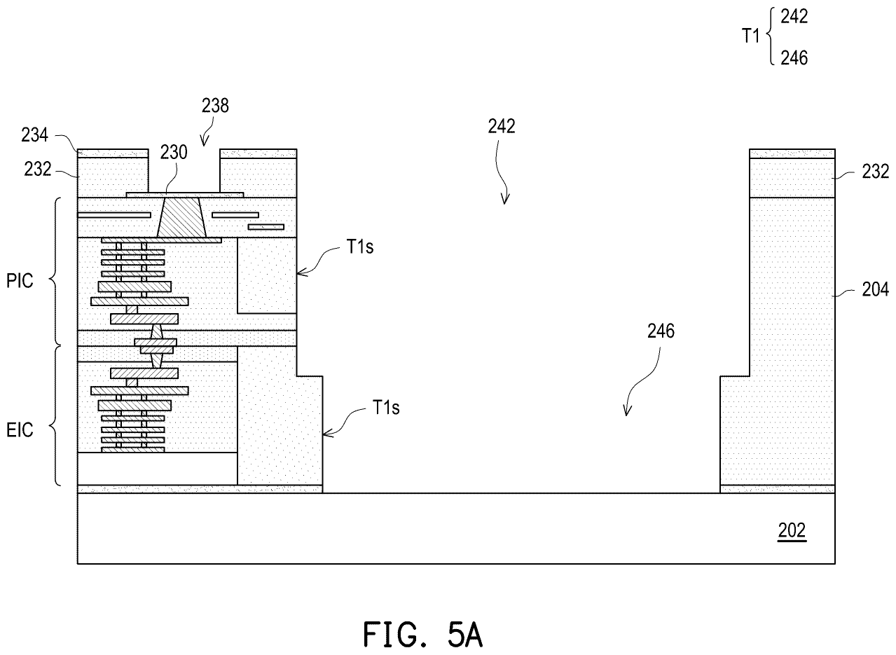

FIG. 4A through 4D illustrate cross-sectional views of a process for the formation of a package structure in accordance with some embodiments of the present disclosure, wherein the reference symbols used in FIG. 2A-2M are used to equally represent the same or similar features. As such, the described features will not be repeated again.

Referring to FIG. 4A, the package structure is the same as that of FIG. 2F except for the shape of the trench T1. The sidewalls T1s of the trench T1 have the stepped profile; however, a trench T2 with a slope sidewall T2s is formed in FIG. 4A. In some embodiments, the method of forming the trench T2 comprises continuously etching the dielectric layer 232 and the encapsulant 204 until a surface of the carrier 202 is exposed, wherein the etching may include a dry etch (e.g., reactive ion etching), a wet etch, and/or combination thereof. In some embodiments, an angle θ between the surface of the carrier 202 and the slope sidewall T2s is more than 90°; for example, the angle θ is more than 91°, more than 92°, or more than 93°. In some embodiments, the angle θ between the surface of the carrier 202 and the slope sidewall T2s is less than 110°; for example, the angle θ is less than 105°, less than 100°, or less than 95°. In some alternative embodiments, the angle θ may be 90°; in other words, the trench T2 may have vertical sidewalls.

In addition, the sidewalls T1s of the trench T1 in FIG. 2F may also has a slope sidewall in which an angle between each sidewall T1s and the horizontal plane is more than 90°. In some embodiments, the angle of the sidewall T1s of the upper recess 242 may be less than that of the sidewall T1s of the lower recess 246 so that step coverage may be improved.

Referring to FIG. 4B, a cover layer 400 is formed on the slope sidewalls T2s of the trench T3 and sidewalls of the opening 238. The formation of the cover layer 400 is the same as the cover layer 248′ of FIG. 2H, which are not repeated herein. After forming the cover layer 400, the buffer layer 230 exposed by the opening 238 is removed, and meanwhile, if the material of the first mask layer 234 is the same as the buffer layer 230, the first mask layer 234 may be thinned to form a thinner first mask layer 234′.

Referring to FIG. 4C, a patterned polymer layer PM1 is formed on the first mask layer 234′, a seed layer SL′ is formed in the opening 238 and on the patterned polymer layer PM1 with a photoresist (not shown), and a conductive portion 250 is plated on the seed layer SL′. Those processes may refer to the steps of FIG. 2H to FIG. 2K, which are not repeated herein.

Referring to FIG. 4D, a redistribution structure 252 may be formed, and a fiber array unit FAU is formed in the trench T2 over the carrier 202. Those processes may refer to the steps of FIG. 2L to FIG. 2M, which are not repeated herein.

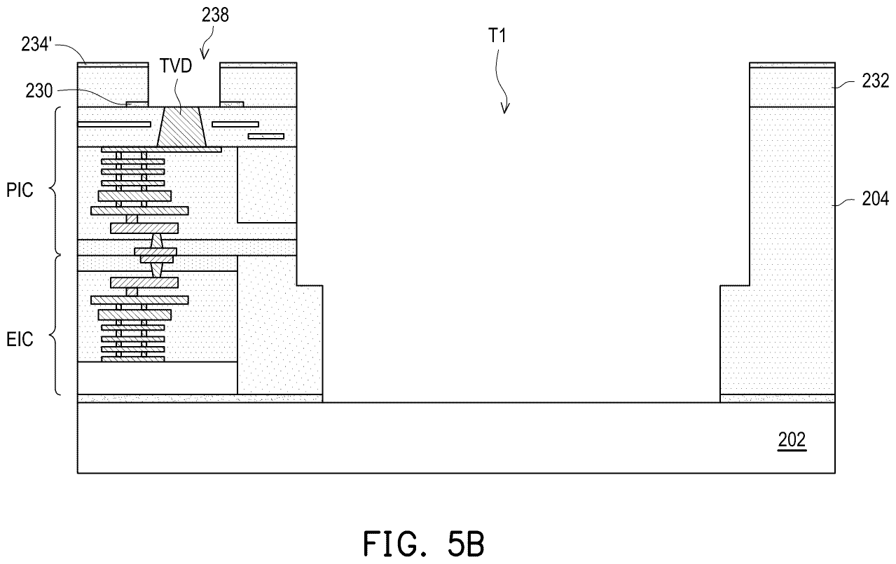

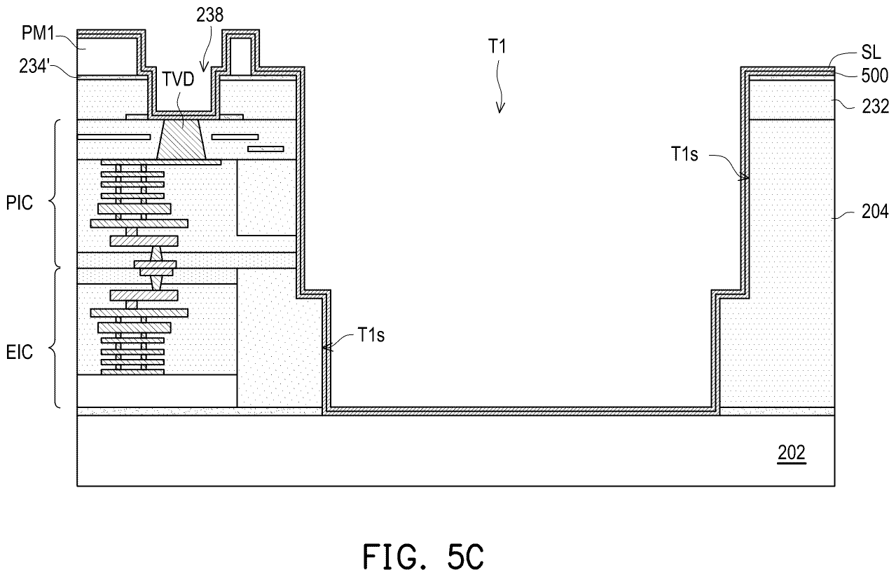

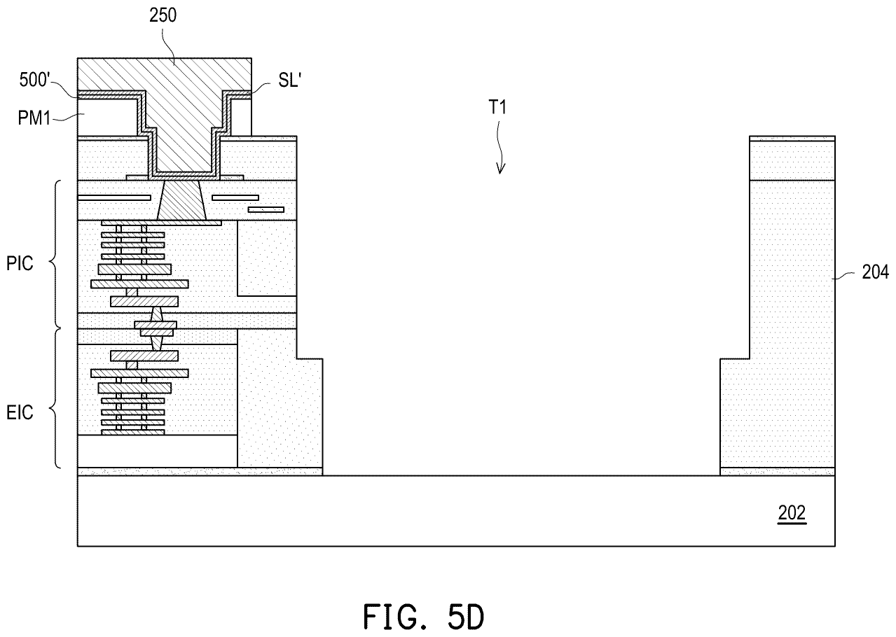

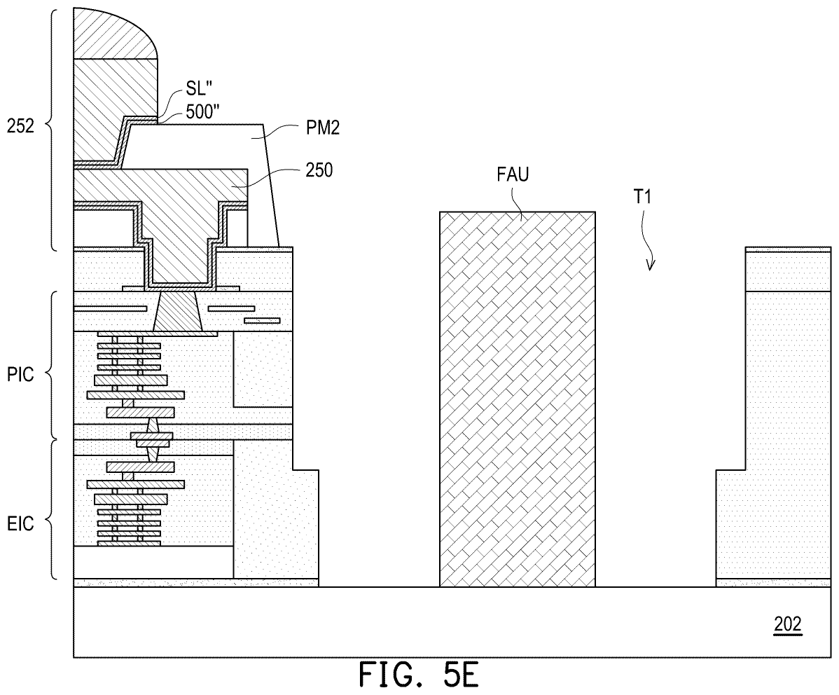

FIG. 5A through 5E illustrate cross-sectional views of a process for the formation of a package structure in accordance with some embodiments of the present disclosure, wherein the reference symbols used in FIG. 2A-2M are used to equally represent the same or similar features. As such, the described features will not be repeated again.

Referring to FIG. 5A, the package structure is the same as that of FIG. 2F after removing the second mask pattern 244. The sidewalls T1s of the trench T1 have a stepped profile. In some alternative embodiments, the trench may be formed the same as the trench T2 of FIG. 4A.

Referring to FIG. 5B, the buffer layer 230 exposed by the opening 238 is removed, and meanwhile, if the material of the first mask layer 234 is the same as the buffer layer 230, the first mask layer 234 may be thinned to form a thinner first mask layer 234′.

Referring to FIG. 5C, a patterned polymer layer PM1 is formed on the first mask layer 234′, and a cover layer 500 and a seed layer SL are sequentially deposited on the trenches T1 and the openings 238 to cover the carrier 202, the encapsulant 204, the dielectric layer 232, the patterned polymer layer PM1, and the sidewalls T1s of the trench T1. In the presence of the cover layer 500, the seed layer SL can continuously deposit on the whole surfaces of the trench T1. In other words, side wall roughness can be improved by the cover layer 500. In some embodiments, a material of the cover layer 500 may be the same as the seed layer SL, and thus the cover layer 500 can be utilized as a seed layer for subsequent plating process. In some embodiments, the method of forming the cover layer 500 and the seed layer SL may include continuously depositing on the whole surfaces of the trench T1 by a PVD process, such as sputtering. For example, the cover layer 500 is a Ti/Cu composited layer.

Referring to FIG. 5D, a conductive portion 250 is plated on the seed layer SL′. Those processes may refer to the steps of FIG. 2J to FIG. 2K, which are not repeated herein. Thereafter, portions of the cover layer 500 and a seed layer SL are removed to remain the seed layer SL′ and the cover layer 500′ below the conductive portion 250.

Referring to FIG. 5E, a redistribution structure 252 may be formed, and a fiber array unit FAU is formed in the trench T1 over the carrier 202. Those processes may refer to the steps of FIG. 2L to FIG. 2M except for the formation of another cover layer 500″ between the seed layer SL″ and the conductive portion 250/the patterned polymer layer PM2.

According to some embodiments, the method of manufacturing the package structure includes providing a carrier on which a plurality of first dies and a plurality of second dies are respectively bonded to form a plurality of stacks, and an encapsulant laterally encapsulating the plurality of stacks; forming a dielectric layer over the stacks and the encapsulant; forming a plurality of openings in the dielectric layer to expose a portion of the plurality of second dies of the stacks; forming a plurality of trenches in gaps among the plurality of stacks through the dielectric layer and the encapsulant to expose the carrier; forming a cover layer on sidewalls of the trenches and sidewalls of the openings; conformally forming a seed layer on the trenches and the openings to cover the carrier, the cover layer, the encapsulant, and the dielectric layer; forming a mask layer to cover a portion of the seed layer and expose the seed layer in the openings; and performing a plating process to form a conductive portion in the openings using the seed layer.

According to some embodiments, the method of manufacturing the package structure includes providing a carrier on which a plurality of electronic integrated circuit (EIC) dies and a plurality of photonic integrated circuit (PIC) dies are respectively bonded to form a plurality of package components, and an encapsulant laterally encapsulating the plurality of package components; forming a dielectric layer over the package components and the encapsulant; forming a plurality of openings in the dielectric layer to expose a conducting portion of each of the plurality of PIC dies; forming a plurality of trenches in gaps among the plurality of package components through the dielectric layer and the encapsulant to expose the carrier; forming a cover layer on sidewalls of the trenches and sidewalls of the openings; conformally forming a seed layer on the trenches and the openings to cover the carrier, the cover layer, the encapsulant, and the dielectric layer; forming a mask layer to cover a portion of the seed layer and expose the seed layer in the openings; performing a plating process to form a conductive portion on the exposed seed layer; removing the mask layer; removing a portion of the seed layer exposed by the conductive portion; forming a redistribution structure over the conductive portion; and forming a FAU within the trenches over the carrier.

According to some embodiments, the package structure includes a first die, a second die bonded to the first die, a redistribution structure over the second die, a dielectric layer between the redistribution structure and the second die, a plurality of conductive portions in the dielectric layer and connecting the redistribution structure with the second die, and a cover layer sandwiched by the dielectric layer and the plurality of conductive portions in a cross-sectional view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a package structure, comprising:
providing a carrier on which a plurality of first dies and a plurality of second dies are respectively bonded to form a plurality of stacks, and an encapsulant laterally encapsulating the plurality of stacks;
forming a dielectric layer over the stacks and the encapsulant;
forming a plurality of openings in the dielectric layer to expose a portion of the plurality of second dies of the stacks;
forming a plurality of trenches in gaps among the plurality of stacks through the dielectric layer and the encapsulant to expose the carrier;
forming a cover layer on sidewalls of the trenches and sidewalls of the openings;
conformally forming a seed layer on the trenches and the openings to cover the carrier, the cover layer, the encapsulant, and the dielectric layer;
forming a mask layer to cover a portion of the seed layer and expose the seed layer in the openings; and
performing a plating process to form a conductive portion in the openings using the seed layer.

2. The method of manufacturing the package structure of claim 1, wherein forming the plurality of trenches comprises etching the dielectric layer and the encapsulant to form the trenches with a slope sidewall.

3. The method of manufacturing the package structure of claim 1, wherein forming the plurality of trenches comprises:
performing a first patterning process to etch the dielectric layer and an upper portion of the encapsulant for forming an upper recess; and
performing a second patterning process to etch a lower portion of the encapsulant under the upper recess for forming a lower recess.

4. The method of manufacturing the package structure of claim 1, wherein the cover layer comprises a titanium/copper (Ti/Cu) composite layer, a silicon nitride layer, an oxide layer, or a combination thereof.

5. The method of manufacturing the package structure of claim 1, wherein after the plating process further comprises:
removing the mask layer; and
removing a portion of the seed layer exposed by the conductive portion.

6. A method of manufacturing a package structure, comprising:
providing a carrier on which a plurality of electronic integrated circuit (EIC) dies and a plurality of photonic integrated circuit (PIC) dies are respectively bonded to form a plurality of package components, and an encapsulant laterally encapsulating the plurality of package components;
forming a dielectric layer over the package components and the encapsulant;
forming a plurality of openings in the dielectric layer to expose a conducting portion of each of the plurality of PIC dies;
forming a plurality of trenches in gaps among the plurality of package components through the dielectric layer and the encapsulant to expose the carrier;
forming a cover layer on sidewalls of the trenches and sidewalls of the openings;
conformally forming a seed layer on the trenches and the openings to cover the carrier, the cover layer, the encapsulant, and the dielectric layer;
forming a mask layer to cover a portion of the seed layer and expose the seed layer in the openings;
performing a plating process to form a conductive portion on exposed seed layer;
removing the mask layer;
removing a portion of the seed layer exposed by the conductive portion;
forming a redistribution structure over the conductive portion; and
forming a fiber array unit (FAU) within the trenches over the carrier.

7. The method of manufacturing the package structure of claim 6, wherein forming the plurality of trenches comprises etching the dielectric layer and the encapsulant to form the trenches with a slope sidewall.

8. The method of manufacturing the package structure of claim 6, wherein forming the plurality of trenches comprises:
performing a first patterning process to etch the dielectric layer and an upper portion of the encapsulant for forming an upper recess; and
performing a second patterning process to etch a lower portion of the encapsulant under the upper recess for forming a lower recess.

9. The method of manufacturing the package structure of claim 6, wherein the cover layer comprises a titanium/copper (Ti/Cu) composite layer, a silicon nitride layer, an oxide layer, or a combination thereof.

10. A package structure, comprising:
a first die;
a second die, bonded to the first die;
a redistribution structure over the second die;
a dielectric layer between the redistribution structure and the second die;
a plurality of conductive portions in the dielectric layer and connecting the redistribution structure with the second die; and
a cover layer sandwiched by the dielectric layer and the plurality of conductive portions in a cross-sectional view.

11. The package structure of claim 10, further comprising a seed layer between the cover layer and the plurality of conductive portions in the cross-sectional view.

12. The package structure of claim 11, wherein the cover layer comprises a silicon nitride layer or an oxide layer.

13. The package structure of claim 10, wherein the conductive portions are a plating film.

14. The package structure of claim 13, wherein the cover layer is a seed layer for the plating film.

15. The package structure of claim 13, wherein the cover layer comprises a titanium/copper (Ti/Cu) composite layer.

16. The package structure of claim 10, wherein the first die is an EIC die, and the second die is a PIC die.

17. The package structure of claim 10, wherein a sidewall of the package structure is a slope in the cross-sectional view.

18. The package structure of claim 17, wherein the cover layer is further disposed on the sidewall of the package structure.

19. The package structure of claim 10, wherein a sidewall of the package structure has a stepped profile in the cross-sectional view.

20. The package structure of claim 19, wherein the cover layer is further disposed on sidewalls of the stepped profile.
